(19) United States
(12) Patent Application Publication
(10) Pub. No.: US 2026/0369322 A1
(43) Pub. Date: Nov. 19, 2026

(54) NON-VOLATILE MEMORY AND A METHOD FOR WRITING TO A NON-VOLATILE MEMORY

(71) Applicant: IMEC VZW, Leuven (BE)

(72) Inventors: Yusuke Higashi, Heverlee (BE); Devin Verreck, Pellenberg (BE); Laurent Breuil, Etterbeek (BE)

(21) Appl. No.: 19/675,463

(22) Filed: May 12, 2026

(30) Foreign Application Priority Data
May 16, 2025 (EP) 25177059.0

(51) Int. Cl. G11C 16/10; G11C 16/04; G11C 16/08

(52) U.S. Cl. CPC G11C 16/10; G11C 16/0483; G11C 16/08

(57) ABSTRACT

A method for writing to a non-volatile memory is provided. The method includes providing holes by gate induced drain leakage in a first transistor of a first string. The method includes injecting the holes into the channel of a second transistor of the first string. The second transistor is a memory transistor of the first string. The method includes programming the second transistor by applying a negative voltage to the word line connected to the second transistor, such that electrons tunnel from a gate to a charge trap of the second transistor. When providing the holes, a first voltage is applied to a first bit line, a second voltage is applied to a second bit line, and a third voltage is applied to a control line connected to the first transistor. A difference between the second and third voltages is smaller than a difference between the first and third voltages.

### CROSS-REFERENCE TO RELATED APPLICATION(S)

The present application is a non-provisional patent application claiming priority to European Patent Application No. EP 25177059.0, filed May 16, 2025, the contents of which are hereby incorporated by reference.

### FIELD OF THE DISCLOSURE

The present disclosure relates to a non-volatile memory and a method for writing to a non-volatile memory.

### BACKGROUND

A non-volatile memory is a type of memory that retains stored data even when it is not powered. One type of non-volatile memory is the 3D NAND flash memory.

### SUMMARY

The present disclosure provides a non-volatile memory with high programming efficiency. The present disclosure provides a highly reliable non-volatile memory that may suppress programming disturbances in the non-volatile memory. The present disclosure further provides for a gate side injection operation of a non-volatile memory. The present disclosure also provides a non-volatile memory that is compact and/or has a high bit density. Additionally, the present disclosure provides the above in a three-dimensional (3D) NAND memory, such as a 3D NAND flash memory.

These and other improvements of the present disclosure are at least partly provided herein and provided by the independent claims. Example embodiments are set out in the independent and/or dependent claims.

According to a first example embodiment, a method for writing to a non-volatile memory is provided. The non-volatile memory includes a first bit line and a second bit line. The non-volatile memory includes a first string and a second string. The first string is connected to the first bit line, and the second string is connected to the second bit line. Each string includes a plurality of transistors. The plurality of transistors includes a selector transistor and a plurality of memory transistors. Each transistor includes a source, a drain, a channel, and a gate, and each memory transistor further includes a charge trap. A first capacitance between the charge trap and the channel of the memory transistor is larger than a second capacitance between the charge trap and the gate of the memory transistor. The non-volatile memory includes a plurality of control lines. The plurality of control lines includes a selector line connected to the gate of the selector transistor of the first string and to the selector transistor of the second string. The plurality of control lines include a plurality of word lines. Each word line is connected to the gate of a memory transistor of the plurality of memory transistors of the first string and to a memory transistor of the plurality of memory transistors of the second string. The method includes providing holes by gate induced drain leakage (GIDL) in a first transistor of the first string. The first transistor is the selector transistor of the first string or one of the plurality of memory transistors of the first string. The method includes injecting the holes into the channel of a second transistor of the first string. The second transistor is one of the plurality of memory transistors of the first string. The method includes programming the second transistor by applying a negative voltage to the word line connected to the second transistor such that electrons tunnel from the gate of the second transistor to the charge trap of the second transistor. When providing the holes, a first voltage is applied to the first bit line, a second voltage is applied to the second bit line, and a third voltage is applied to the control line connected to the first transistor. The first voltage is positive, and the third voltage is negative. The difference between the second and third voltages is smaller than the difference between the first and third voltages.

The non-volatile memory may be a semiconductor channel based non-volatile memory. For example, the non-volatile memory may be a flash memory, such as a NAND memory, e.g., a 3D NAND flash memory.

For each string, the transistors of the string may be connected in series. Within the string, the drain of each transistor may be connected to the source of a consecutive transistor. The string may extend vertically. The selector transistor may be arranged at one end of the string, e.g., at a top end or a bottom end. Each memory transistor may constitute a memory cell. The string may include, for example, 32 to 256 (e.g., or more) memory transistors.

Each selector transistor may be a string select transistor (SSL). The selector transistor may be arranged to connect one end of the string to the bit line of the string. The selector transistor may isolate the selected string from other strings in the non-volatile memory, such that operations on one string do not affect other strings.

Each memory transistor further includes a charge trap. A first capacitance between the charge trap and the channel of the memory transistor is larger than a second capacitance between the charge trap and the gate of the memory transistor. The memory transistors may be considered (e.g., seen as) gate side injection memory transistors. When the capacitance between the charge trap and the channel is larger than the capacitance between the charge trap and the gate, charge carriers may be tunneled from the gate to the charge trap. For example, it may be easier to tunnel charge carriers from the gate to the charge trap than from the channel to the charge trap. There may be two types of charge carriers of opposite charge, such as electrons and holes.

The memory transistors may be programmed by tunnelling electrons from the gate to the charge trap, in contrast to a conventional approach where the electrons tunnel from the channel to the charge trap.

The charge trap may be referred to as a charge trapping layer or a floating gate. The charge trap may be arranged between the gate and the channel of the transistor. A first dielectric layer may be arranged between the charge trap and the channel, and a second dielectric layer may be arranged between the charge trap and the gate. The first dielectric layer may be thicker than the second dielectric layer, e.g., at least 50% thicker or at least 100% thicker to facilitate the first capacitance being larger than the second capacitance. Additionally, or alternatively, the first and second dielectric layers may comprise different dielectric materials. The first and second dielectric layers may comprise oxide.

The first dielectric layer may be referred to as a block oxide layer. The first dielectric layer may include, for example, HfO₂, HfZrOx, AlOx, or SiO₂.

The second dielectric layer may be referred to as a tunnel oxide layer. The second dielectric layer may include, for example, SiO₂ or SiON.

The first and second dielectric layers may include a plurality of different dielectric material layers (e.g., AlOx and SiO₂ for the first dielectric layer and SiON and HfO₂ for the second dielectric layer).

For example, each of the plurality of memory transistors may include a tunnel oxide layer arranged between the charge trap and the gate, and a blocking oxide layer arranged between the charge trap and the channel of the memory transistor.

The gate side injection operation herein facilitates high programming efficiency. For a conventional channel side injection operation, the maximum programming efficiency may be limited to 1. For a gate side injection operation, the maximum programming efficiency may be the ratio between the first capacitance divided by the second capacitance. As provided herein, for a gate side injection operation, the programming efficiency may be above 1.

For example, as provided herein, a ratio of the first capacitance over the second capacitance may be between 1 and 10. Such a ratio may facilitate high programming efficiency.

Programming disturbances may be suppressed in a different manner in gate side injection operation, as compared to channel side injection operation. Applying a negative voltage to the word line of a memory transistor, such as the second transistor described hereinabove, during programming may indicate that suppression of programming disturbances using conventional schemes works less effectively or not at all.

Injecting holes into the channel of the memory transistor to be programmed (e.g., the second transistor of the first string) may facilitate programming of the memory transistor by gate side injection. For example, if there are holes in the channel of a memory transistor, electrons may be (e.g., more easily) tunneled from the gate to the charge trap of the memory transistor, attributable to the higher electric field, e.g., the negatively charged electrons may be tunneled in the direction towards the positively charged holes on the opposite side of the charge trap, which may facilitate a high programming efficiency.

If the holes are provided in the first string by GIDL (e.g., GIDL in a transistor different from the second transistor, such as the first transistor), then the second string may be deprived of holes when the difference between the second and third voltages is smaller than the difference between the first and third voltages. In other words, the first string may be provided with holes, which facilitates gate side injection and thereby facilitates programming, while the second string is deprived of holes, which inhibits gate side injection (e.g., and thereby inhibits programming disturbances).

GIDL generates holes due to band-to-band tunnelling. Herein, electrons may tunnel through the energy barrier between the valence band and the conduction band, thereby creating holes. GIDL may be controlled by controlling the potential difference between the drain or source and the gate of a transistor.

During the formation of holes in the first transistor of the first string, the third voltage is applied to the control line (e.g., selector line or word line) of the first transistor of the first string, thereby applying the third voltage to the gate of the first transistor of the first string. The third voltage may (e.g., simultaneously) be applied, via the control line, to a first transistor of the second string.

As mentioned hereinabove, the first voltage is applied to the first bit line, and a second voltage is applied to the second bit line. Thus, the first voltage may be applied to the drain of the first transistor of the first string, and the second voltage may be applied to the drain of the first transistor of the second string. Since the first transistor of the first string and the first transistor of the second string are provided with the same voltage (e.g., third voltage), setting a difference between the second and third voltages to be smaller than a difference between the first and third voltages may provide that the potential difference between the drain and the gate of the first transistor of the first string is smaller than the potential difference between the drain and the gate of the first transistor of the second string. Thus, while there is GIDL in the first transistor of the first string, GIDL in the first transistor of the second string may be smaller or (e.g., completely) prevented. Accordingly, more holes may be provided in the first string than in the second string.

As mentioned hereinabove, the holes provided by GIDL in the first transistor of the first string are injected into the second transistor of the first string. The second transistor of the first string may be a transistor further away from the first bit line than the first transistor of the first string. A second transistor of the second string may be connected to the (e.g., same) control line as the second transistor of the first string. The second transistor of the first string may be a transistor on the source side of the first transistor of the first string (e.g., the same relationship may also apply to the first and second transistors of the second string).

The holes may be injected by providing a (e.g., suitable) voltage on the control line of the second transistor of the first string in relation to the first transistor of the first string and/or providing (e.g., suitable) voltages on any intermediate control line between the first and second transistors of the first string. As the control lines may be connected to the gates of corresponding transistors on the first and second strings, the voltages may also be provided to the second string. Since GIDL is inhibited in the first transistor of the second string, there may be few holes or no holes to inject into the channel of the second transistor of the second string. Thus, (e.g., erroneous programming by) programming disturbances may be inhibited in the second transistor of the second string.

The method may be configured such that, when (e.g., during the act of) providing holes by GIDL in the first transistor of the first string, a hole current through the first string is at least a factor of (e.g., about) 10 times larger (e.g., at least a factor of 50 times larger or at least a factor of 100 times larger) than a hole current through the second string. Thus, there may be fewer holes in the second transistor of the second string compared to the second transistor of the first string, e.g., at least a factor of 10 times fewer, which may facilitate a (e.g., sufficient) suppression of programming disturbances in the second transistor of the second string.

The first, second, and third voltages may be configured such that a hole current through the first string is at least a factor of (e.g., about) 10 times larger than a hole current through the second string during the act of providing holes by GIDL in the first transistor of the first string.

The method may be configured such that the second voltage is negative, which may further inhibit GIDL in the first transistor of the second string and thereby suppress programming disturbances in the second transistor of the second string.

The method may be configured such that the difference between the second and third voltages is less than 70% of the difference between the first and third voltages, which may further inhibit GIDL in the first transistor of the second string and thereby suppress programming disturbances in the second transistor of the second string. For example, the difference between the second and third voltages may be less than 50% of the difference between the first and third voltages. As a further example, the first voltage may be 3V (Volts), the second voltage may be -3V, and the third voltage may be -7V. In the latter example, the difference between the second and third voltages is 4V and the difference between the first and third voltages is 10V, i.e., the difference between the second and third voltages is 40% of the difference between the first and third voltages.

The method may be configured such that the difference between the first and third voltages is at least 7V, which may facilitate (e.g., sufficient) GIDL in the first transistor of the first string.

The method may be configured such that the respective channels of the memory transistors of the first string are intrinsically doped, and the use of GIDL may be useful. In recent 3D NAND memories, the dopant concentration of the channels of the strings is intrinsic. Such channels do not connect to the p-type well. The creation of holes may, in such cases, be controlled by GIDL.

The programming of the second transistor of the first string may include applying a series of negative voltage pulses to the word line connected to the second transistor of the first string, with each subsequent pulse of the series of negative pulses increasing in amplitude. The amplitude may be increased until a threshold voltage target is met (e.g., achieved). Such series of negative voltage pulses helps to provide a tighter distribution of threshold voltages in the memory transistors. Improved (e.g., more precise) control over the final programmed state is facilitated by applying incremental changes in programming pulses. Such (e.g., a series of) negative voltage pulses may further reduce (e.g., minimize) the programming disturbances to neighboring memory transistors. In view of the above, incremental step pulse programming (ISPP) may be used for programming the second transistor of the first string.

The method may be configured such that the third voltage is initiated after (e.g., subsequent to) the initiation of the first and second voltages, which may further suppress programming disturbances in the second transistor of the second string.

The method may be implemented using GIDL in the selector transistor of the first string or in a memory transistor of the first string. Below, an example embodiment A provides (e.g., describes) for using GIDL in the selector transistor of the first string, and an example embodiment B provides (e.g., describes) for using GIDL in a memory transistor of the first string.

### Example Embodiment A

In example embodiment A, the method may be configured such that the first transistor of the first string is the selector transistor, and the first and second transistors are separated by at least one memory transistor of the plurality of memory transistors of the first string. Injecting the holes into the channel of the second transistor includes applying a negative voltage to the word line of the at least one memory transistor separating the first transistor and the second transistor, such that the holes provided in the first transistor pass through the channel of the at least one memory transistor separating the first transistor and the second transistor.

The negative voltage applied to the word line of the at least one memory transistor separating the first transistor and the second transistor may be less negative than the programming voltage applied to the word line connected to the second transistor of the first string.

The negative voltage applied to the word line of the at least one memory transistor separating the first transistor and the second transistor may be the same as the third voltage or between the third voltage and the programming voltage applied to the word line connected to the second transistor of the first string. Using GIDL in the selector transistor may also be applicable when the second transistor is adjacent to the first transistor, such as when the second transistor is the memory transistor next to the selector transistor.

Further, the negative voltage applied to the word line of the at least one memory transistor separating the first transistor and the second transistor may be initiated after (e.g., subsequent to) the initiation of the third voltage, which may further suppress programming disturbances in the second transistor of the second string.

### Example Embodiment B

In example embodiment B, the method may be configured such that the first transistor and the second transistor of the first bit string are (e.g., adjacent) memory transistors of the plurality of memory transistors of the first string, and the first transistor and the first bit line are separated by at least one further transistor of the first string. The method further includes applying a positive voltage to the control line of the at least one further transistor separating the first transistor and the first bit line, such that the voltage of the first bit line propagates through the at least one further transistor.

Thus, the first and second transistors of the first string may be (e.g., neighboring) memory transistors of the first bit line. For example, there may be no transistors between the first and second transistors of the first string.

The positive voltage applied to the control line of the at least one further transistor separating the first transistor and the first bit line may be configured to turn on the at least one further transistor separating the first transistor and the first bit line. The positive voltage applied to the control line of the at least one further transistor separating the first transistor and the first bit line may be higher than the first voltage. The voltages of the control lines of the at least one further transistor separating the first transistor and the first bit line may not (e.g., all) have the same value.

Further, the first and second voltages may be initiated after (e.g., subsequent to) the initiation of the positive voltage applied to the control line of the at least one further transistor separating the first transistor and the first bit line.

The memory transistors may be programmed sequentially.

Thus, in example embodiment B, the method, after (e.g., subsequent to) programming the second transistor, may further include, providing holes by GIDL in a third transistor of the first string. The third transistor may be positioned on an opposite side of the first transistor relative to the second transistor. The method also may include injecting the holes provided by GIDL in the third transistor into the channel of the first transistor of the first string, and programming the first transistor by applying a negative voltage to the control line connected to the first transistor, such that electrons tunnel from the gate of the first transistor to the charge trap of the first transistor.

The memory transistor which provides the holes by GIDL (e.g., first transistor) may (e.g., subsequently) be programmed. During programming, a further transistor (e.g., third transistor) may provide the holes. Programming may start with a memory transistor a distance away from the first bit line, e.g., furthest away from the first bit line.

In an example where the string extends vertically, the first bit line is arranged over the string, and the selector transistor is arranged at the top end of the string, followed by memory transistors 1 to a number (n) (e.g., below), such that memory transistor 1 is closest to the first bit line and memory transistor n is furthest away. For example, programming may start with programming the memory transistor n (e.g., second transistor) while using a memory transistor n-1 (e.g., first transistor) as the transistor for providing the holes by GIDL. Subsequently, the memory transistor n-1 may be programmed, while using memory transistor n-2 (e.g., third transistor) to provide the holes by GIDL. Programming may then continue with one memory transistor at a time (e.g., upwards) until (e.g., all) the memory transistors of the first string (e.g., or at least a bottom part of the memory transistors of the first string) are programmed.

According to a second example embodiment, a non-volatile memory is provided. The non-volatile memory includes a first bit line and a second bit line. The non-volatile memory includes a first string and a second string. The first string is connected to the first bit line, and the second string is connected to the second bit line. Each string includes a plurality of transistors. The plurality of transistors includes a selector transistor and a plurality of memory transistors. Each transistor includes a source, a drain, a channel, and a gate, and each memory transistor further includes a charge trap. A first capacitance between the charge trap and the channel of the memory transistor is larger than a second capacitance between the charge trap and the gate of the memory transistor. The non-volatile memory includes a plurality of control lines. The plurality of control lines includes a selector line connected to the gate of the selector transistor of the first string and to the selector transistor of the second string. The plurality of control lines includes a plurality of word lines. Each word line is connected to the gate of a memory transistor of the plurality of memory transistors of the first string and to a memory transistor of the plurality of memory transistors of the second string. The non-volatile memory includes a controller. The controller is configured to provide holes by gate induced drain leakage (GIDL) in a first transistor of the first string. The first transistor is the selector transistor of the first string or one of the plurality of memory transistors of the first string. The controller is configured to inject the holes into the channel of a second transistor of the first string. The second transistor is one of the plurality of memory transistors of the first string. The controller is configured to program the second transistor by applying a negative voltage to the word line connected to the second transistor such that electrons tunnel from the gate of the second transistor to the charge trap of the second transistor. When (e.g., during) providing the holes, a first voltage is applied to the first bit line, a second voltage is applied to the second bit line, and a third voltage is applied to the control line connected to the first transistor. In an example, the first voltage is positive, and the third voltage is negative. A difference between the second and third voltages is smaller than a difference between the first and third voltages.

A device according to the second example embodiment may have the same or similar improvements and/or uses as the improvements and/or uses described in conjunction with the first example embodiment herein.

The controller may be any (e.g., form of) voltage controller for controlling the voltages of the control lines and the bit lines.

### BRIEF DESCRIPTION OF THE FIGURES

The above, as well as additional objects, features, and uses of the present disclosure, may be better understood through the following illustrative and non-limiting detailed description, with reference to the appended drawings. In the drawings, like reference numerals may be used for like elements.

FIG. 1A illustrates a non-volatile memory of an example embodiment of the present disclosure.

FIG. 1B illustrates a selector transistor of an example embodiment of the present disclosure.

FIG. 1C illustrates a memory transistor of an example embodiment of the present disclosure.

FIG. 2 illustrates a non-volatile memory of an example embodiment of the present disclosure.

FIG. 3 illustrates a non-volatile memory of an example embodiment of the present disclosure.

FIG. 4 illustrates a non-volatile memory of an example embodiment of the present disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the example embodiments set forth herein; rather, these embodiments are provided by way of example. Furthermore, like numbers refer to the same or similar elements or components throughout.

As shown in the attached drawings, the technical contents and detailed description of the present disclosure are described herein according to example embodiments, which are not to limit the claimed scope. The present disclosure may be embodied in many different forms and may not be construed as limited to the example embodiments set forth herein; rather, these example embodiments are provided for completeness, and to fully convey the scope of the present disclosure.

In the following, axes X, Y, and Z indicate a first horizontal direction, a second horizontal direction transverse to the first horizontal direction, and a vertical direction, respectively. The X-direction and Y-direction may be parallel to a main plane of a substrate on which the non-volatile memory is arranged. The Z-direction may be parallel to a normal direction of the substrate.

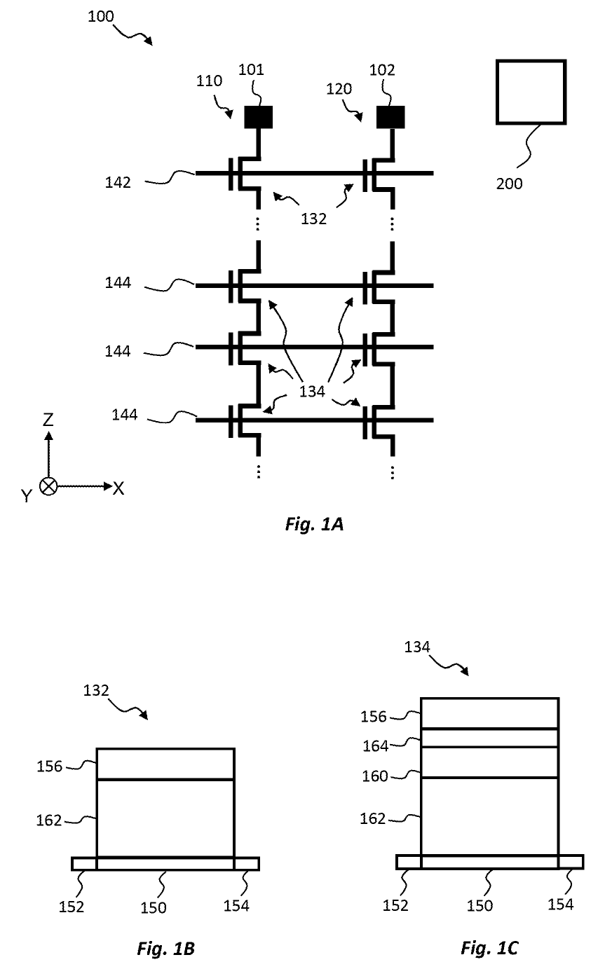

FIG. 1A is a schematic illustration of a non-volatile memory 100 of an example embodiment of the present disclosure. The non-volatile memory 100 includes a first bit line 101, a second bit line 102, a first string 110, and a second string 120. The first string 110 is connected to the first bit line 101. The second string 120 is connected to the second bit line 102. As shown, the non-volatile memory 100, the first bit line 101 and the second 102 bit line extend in the Y-direction.

Each string 110, 120 includes a plurality of transistors. The plurality of transistors includes a selector transistor 132 and a plurality of memory transistors 134. Each string 110, 120 may include additional (e.g., further) memory transistors 134 (e.g., than the ones shown), as indicated by the dotted lines of each string (e.g., as shown in the figures). Additionally, the non-volatile memory 100 may include additional (e.g., further) bit lines and additional (e.g., further) strings.

In the illustrated non-volatile memory 100, the strings 110, 120 extend vertically (e.g., in the Z-direction), and the first bit line 101 and second 102 bit line are arranged above the first string 110 and second string 120, respectively. In the illustrated non-volatile memory 100, the selector transistor 132 of each string is arranged at the top end and connected to the respective bit line.

FIGS. 1B and 1C are schematic illustrations of a selector transistor 132 and a memory transistor 134, respectively, of an example embodiment. Each transistor (e.g., both the selector transistor 132 and the memory transistor 134) includes a source 152, a drain 154, a channel 150, and a gate 156. The memory transistor 134 further includes a charge trap 160. In an example embodiment, each string of the non-volatile memory 100 may be arranged in a vertical hole of the non-volatile memory 100. Sources 152, drains 154, and channels 150 of the transistors may be integrated in a first layer along an inner wall of the hole. Gates 156 may be integrated in a second layer along the inner wall of the hole. Charge traps 160 may be integrated in a third layer along the inner wall of the hole, between the first and second layers. As illustrated in FIG. 1C, the memory transistors 134 may include a blocking oxide layer 162 (e.g., first dielectric layer) arranged between the charge trap 160 and the channel 150, and a tunnel oxide layer 164 (e.g., second dielectric layer) arranged between the charge trap 160 and the gate 156. In an example embodiment, the blocking oxide layer 162 may be thicker than the tunnel oxide layer 164, e.g., at least 50% thicker or at least 100% thicker. As illustrated in FIG. 1B, the selector transistors 132 may include a blocking oxide layer 162 (e.g., solely a blocking oxide layer 162) between the channel 150 and the gate 156. A first capacitance between the charge trap 160 and the channel 150 of the memory transistor 134 may be larger than a second capacitance between the charge trap 160 and the gate 156 of the memory transistor 134, e.g., as a result of thicknesses and/or materials of the blocking oxide layer 162 and the tunnel oxide layer 164.

Referring back to FIG. 1A, the illustrated non-volatile memory 100 further includes a selector line 142 connected to the gate 156 of the selector transistor 132 of the first string 110 and to the gate 156 of the selector transistor 132 of the second string 120. The illustrated non-volatile memory 100 further includes a plurality of word lines 144. Each word line 144 is connected to the gate 156 of the memory transistor 134 of the first string 110 and to the gate 156 of the memory transistor 134 of the second string 120. The selector line 142 and the word lines 144 may collectively be referred to as control lines. As shown in the non-volatile memory 100, the control lines extend in the X-direction.

The non-volatile memory 100 of FIG. 1A further includes a controller 200 for controlling the voltages of the control lines 142, 144 and the bit lines 101, 102.

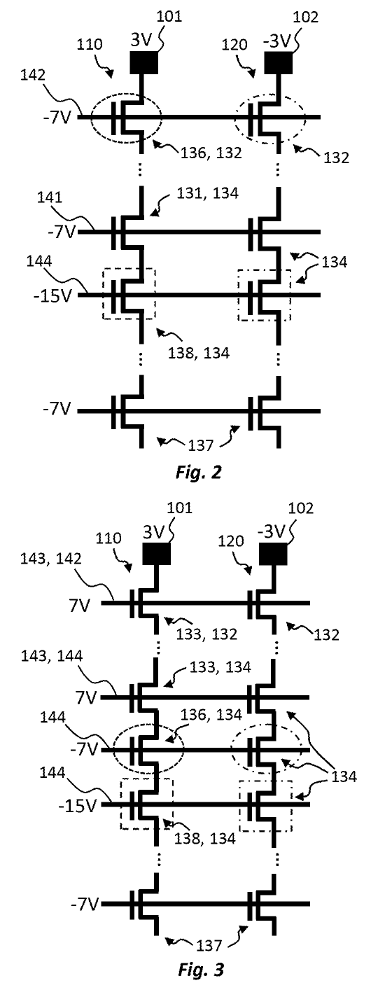

The method will be described according to the above-mentioned examples. In example embodiment A, the holes are provided by GIDL in the selector transistor 132 of the first string 110, as illustrated in FIG. 2. In example embodiment B, the holes are provided by GIDL in the memory transistor 134 of the first string 110, as illustrated in FIG. 3. In the figures, transistors where GIDL occur are marked by dashed ellipses, and transistors where GIDL is inhibited are marked by dash-dotted ellipses. Memory transistors 134 where programming occurs are marked by dashed squares, and memory transistors where programming is inhibited are marked by dash-dotted squares.

FIG. 2 shows the example embodiment A providing holes by GIDL in a first transistor 136 of the first string 110. In FIG. 2, the first transistor 136 is the selector transistor 132 of the first string 110. In FIG. 2, 3V is applied to the drain of the first transistor 136 and -7V is applied to the gate of the first transistor 136, thereby causing GIDL.

FIG. 2 further shows injecting the holes into the channel 150 of a second transistor 138 of the first string 110. The second transistor 138 is one of the memory transistors 134 of the first string 110. In FIG. 2, the holes are injected by applying a negative voltage (e.g., -7V) to the word line 141 of memory transistors 131 separating the first transistor 136 and the second transistor 138, such that the holes provided in the first transistor 136 pass through the channels 150 of the memory transistors 131 separating the first transistor 136 and the second transistor 138.

FIG. 2 further shows programming the second transistor 138 by applying a negative voltage (e.g., -15V) to the word line 144 connected to the second transistor 138, such that electrons tunnel from the gate 156 of the second transistor 138 to the charge trap 160 of the second transistor 138.

In FIG. 2, during the act of (e.g., when) providing the holes, a first voltage is applied to the first bit line 101, a second voltage is applied to the second bit line 102, and a third voltage is applied to the control line (e.g., selector line 142) connected to the first transistor 136. In the illustrated example embodiment, the first voltage is 3V, the second voltage is -3V, and the third voltage is -7V. Thus, as illustrated in FIG. 2, the first voltage is positive, the third voltage is negative, and the difference between the second and third voltages (e.g., 4V) is smaller than the difference between the first and third voltages (e.g., 10V). Thus, as illustrated in FIG. 2, while GIDL occurs in the selector transistor 132 of the first string 110, GIDL is inhibited in the selector transistor 132 of the second string 120.

In the example embodiment, a voltage of -7V may be applied to the gates of the memory transistors 134 below the second transistor 138. Further, a voltage of –7V may be applied to the gate of a bottom selector transistor 137.

Other voltages than the voltages of the example embodiment may be used. The above-mentioned voltages may not be initiated simultaneously. For example, the third voltage may be initiated after (e.g., subsequent to) the initiation of the first and second voltages. Further, the negative voltage applied to the word lines 141 of the memory transistors 131 separating the first transistor 136 and the second transistor 138 may be initiated after (e.g., subsequent to) the initiation of the third voltage.

FIG. 3 shows example embodiment B providing holes by GIDL in a memory transistor 134 of the first string 110. Thus, in FIG. 3, the first transistor 136 (e.g., where GIDL occurs) is one of the memory transistors 134 of the first string 110. Further, in FIG. 3, the second transistor 138 (e.g., where the memory transistor 134 is programmed) is adjacent to the first transistor 136. FIG. 3 further shows further transistors 133 of the first string 110 between the first transistor 136 and the first bit line 101. In FIG. 3, the further transistors 133 include both the selector transistor 132 and memory transistors 134.

In FIG. 3, 3V is applied to the first bit line 101 and a positive voltage (e.g., 7V) is applied to control lines 143 of the further transistors 133 separating the first transistor 136 and the first bit line 101, such that the voltage (e.g., 3V) of the first bit line 101 propagates through the further transistors 133. Thus, in the example embodiment, 3V is applied to the drain of the first transistor 136. Further, in the example embodiment, -7V is applied to the gate of the first transistor 136, thereby causing GIDL.

In FIG. 3, -15V is applied to the word line 144 connected to the second transistor 138. Thereby, holes are injected into the channel 150 of the second transistor 138 of the first string 110, and the second transistor 138 is programmed by electrons tunnelling from the gate 156 of the second transistor 138 to the charge trap 160 of the second transistor 138.

In FIG. 3, during the act of providing the holes, a first voltage is applied to the first bit line 101, a second voltage is applied to the second bit line 102, and a third voltage is applied to the control line connected to the first transistor 136. In the illustrated example embodiment, the first voltage is 3V, the second voltage is -3V, and the third voltage is -7V. Thus, as illustrated in FIG. 3, the first voltage is positive, the third voltage is negative, and the difference between the second and third voltages (e.g., 4V) is smaller than the difference between the first and third voltages (e.g., 10V). Thus, as illustrated in FIG. 3, although there is a corresponding memory transistor 134 in the second string 120 connected to the same word line 144 as the first transistor 136 of the first string 110, GIDL only occurs in the first transistor 136 and not in the corresponding memory transistor 134 of the second string 120.

In the example embodiment, a voltage of -7V may be applied to the gates of memory transistors 134 below the second transistor 138. Further, for example, a voltage of –7V may be applied to the gate of a bottom selector transistor 137.

Other voltages than the voltages of the example embodiment may be used. The above-mentioned voltages may not be initiated simultaneously. For example, the third voltage may be initiated after (e.g., subsequent to) the initiation of the first and second voltages. Further, the first and second voltages may be initiated after (e.g., subsequent to) the initiation of the positive voltage applied to the control lines 143 of the further transistors 133 separating the first transistor 136 and the first bit line 101.

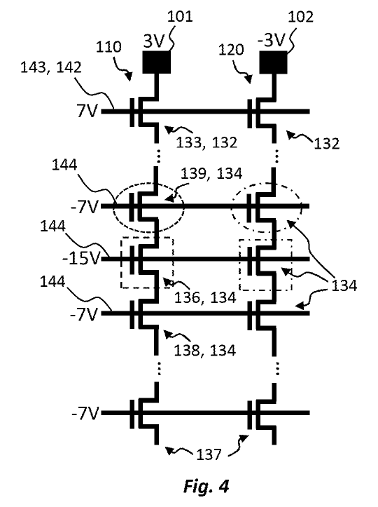

The memory transistors 134 may be programmed sequentially, as illustrated in FIG. 4.

FIG. 4 illustrates a step after (e.g., subsequent to) the step provided in FIG. 3. For example, the step provided in FIG. 4 may be after (e.g., subsequent to) programming the second transistor 138 as provided in FIG. 3. As shown in FIG. 4, holes are provided by GIDL in a third transistor 139 of the first string 110. The third transistor 139 is positioned on an opposite side of the first transistor 136 relative to the second transistor 138, e.g., on the side towards the first bit line 101, as shown. The holes provided by GIDL in the third transistor 139 are injected into the channel 150 of the first transistor 136 of the first string 110. The first transistor 136 is programmed by applying a negative voltage to the control line 144 connected to the first transistor 136 such that electrons tunnel from the gate 156 of the first transistor 136 to the charge trap 160 of the first transistor 136.

In the above, example embodiments of the present disclosure are (e.g., mainly) described with reference to a (e.g., limited) number of examples. However, other examples (e.g., than the ones disclosed above) are (e.g., equally) possible within the scope of the present disclosure .

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for writing to a non-volatile memory, the non-volatile memory comprising:
a first bit line;
a second bit line;
a first string, wherein the first string is connected to the first bit line;
a second string, wherein the second string is connected to the second bit line, wherein each of the first string and the second string comprises a plurality of transistors, wherein the plurality of transistors comprises a selector transistor and a plurality of memory transistors, wherein each transistor of the plurality of transistors comprises a source, a drain, a channel, and a gate, wherein each memory transistor further comprises a charge trap, wherein a first capacitance between the charge trap and the channel of each memory transistor is larger than a second capacitance between the charge trap and the gate of each memory transistor; and
a plurality of control lines comprising:
a selector line connected to the gate of one selector transistor of the first string and to one selector transistor of the second string; and
a plurality of word lines, wherein each word line is connected to the gate of one memory transistor of the plurality of memory transistors of the first string and to one memory transistor of the plurality of memory transistors of the second string;
the method comprising:
providing holes by gate induced drain leakage (GIDL) in a first transistor of the first string, wherein the first transistor is the selector transistor of the first string or one memory transistor of the plurality of memory transistors of the first string;
injecting the holes into the channel of a second transistor of the first string, wherein the second transistor is one memory transistor of the plurality of memory transistors of the first string; and
programming the second transistor by applying a negative voltage to a word line connected to the second transistor, such that electrons tunnel from the gate of the second transistor to the charge trap of the second transistor;
wherein providing the holes includes applying a first voltage to the first bit line, applying a second voltage to the second bit line, and applying a third voltage to a control line of the plurality of control lines connected to the first transistor, wherein the first voltage is positive and the third voltage is negative, wherein a difference between the second voltage and the third voltage is smaller than a difference between the first voltage and the third voltage.

2. The method according to claim 1, wherein a ratio of the first capacitance to the second capacitance is between 1 and 10.

3. The method according to claim 1, wherein when providing holes by GIDL in the first transistor of the first string, a hole current through the first string is a factor of at least 10 greater than a hole current through the second string.

4. The method according to claim 1, wherein the second voltage is negative.

5. The method according to claim 1, wherein the difference between the second and third voltages is less than 70% of the difference between the first and third voltages.

6. The method according to claim 1, wherein the difference between the first and third voltages is at least 7 Volts.

7. The method according to claim 1, wherein each channel of each memory transistor of the first string is intrinsically doped.

8. The method according to claim 1, wherein programming the second transistor includes applying a series of negative voltage pulses to a word line connected to the second transistor of the first string, wherein each subsequent pulse of the series of negative pulses increases in amplitude.

9. The method according to claim 1, wherein the third voltage is initiated after the initiation of the first and second voltages.

10. The method according to claim 1, wherein the first transistor of the first string is the selector transistor, and the first transistor and the second transistor are separated by at least one memory transistor of the plurality of memory transistors of the first string, wherein injecting the holes into the channel of the second transistor comprises applying a negative voltage to a word line of the at least one memory transistor separating the first transistor and the second transistor, such that the holes provided in the first transistor pass through the channel of the at least one memory transistor separating the first transistor and the second transistor.

11. The method according to claim 10, wherein the negative voltage applied to the word line of the at least one memory transistor separating the first transistor and the second transistor is the same voltage as the third voltage.

12. The method according to claim 11, wherein the negative voltage applied to the word line of the at least one memory transistor separating the first transistor and the second transistor is initiated after the initiation of the third voltage.

13. The method according to claim 1, wherein the first transistor and the second transistor are adjacent memory transistors of the plurality of memory transistors of the first string, wherein the first transistor and the first bit line are separated by at least one further transistor of the first string, wherein the method further comprises applying a positive voltage to a control line of the plurality of control lines of the at least one further transistor separating the first transistor and the first bit line, such that the positive voltage of the first bit line propagates through the at least one further transistor.

14. The method according to claim 13, wherein the first and second voltages are initiated after the initiation of the positive voltage applied to the control line of the at least one further transistor separating the first transistor and the first bit line.

15. The method according to claim 14, the method further comprising, after programming the second transistor:
providing holes by GIDL in a third transistor of the first string, wherein the third transistor is positioned on an opposite side of the first transistor relative to the second transistor;
injecting the holes provided by GIDL in the third transistor into the channel of the first transistor of the first string; and
programming the first transistor by applying a negative voltage to a control line of the plurality of control lines connected to the first transistor, wherein electrons tunnel from the gate of the first transistor to the charge trap of the first transistor.

16. The method according to claim 15, wherein the third voltage is simultaneously applied via the control line to a first transistor of the second string.

17. The method according to claim 1, wherein the second transistor of the first string is a first distance away from the first bit line and the second transistor of the first string is a second distance from the first transistor of the first string, wherein the first distance is greater than the second distance.

18. The method according to claim 1, wherein a second transistor of the second string is connected to the same control line as the second transistor of the first string.

19. The method according to claim 1, wherein the second transistor of the first string is on a source side of the first transistor of the first string.

20. A non-volatile memory, the non-volatile memory comprising:
a first bit line;
a second bit line;
a first string, wherein the first string is connected to the first bit line
a second string, wherein the second string is connected to the second bit line, wherein each of the first string and the second string comprises a plurality of transistors, wherein the plurality of transistors comprises a selector transistor and a plurality of memory transistors, wherein each transistor of the plurality of transistors comprises a source, a drain, a channel, and a gate, wherein each memory transistor of the plurality of memory transistors further comprises a charge trap, wherein a first capacitance between the charge trap and the channel of each memory transistor is larger than a second capacitance between the charge trap and the gate of each memory transistor;
a plurality of control lines comprising:
a selector line connected to the gate of one selector transistor of the first string and to one selector transistor of the second string; and
a plurality of word lines, wherein each word line of the plurality of word lines is connected to the gate of one memory transistor of the plurality of memory transistors of the first string and to one memory transistor of the plurality of memory transistors of the second string; and
a controller, wherein the controller is configured to:
provide holes by gate induced drain leakage (GIDL) in a first transistor of the first string, wherein the first transistor is the selector transistor of the first string or one memory transistor of the plurality of memory transistors of the first string;
inject the holes into the channel of a second transistor of the first string, wherein the second transistor is one memory transistor of the plurality of memory transistors of the first string; and
program the second transistor by applying a negative voltage to a word line connected to the second transistor such that electrons tunnel from the gate of the second transistor to the charge trap of the second transistor;
wherein, providing the holes includes applying a first voltage to the first bit line, applying a second voltage to the second bit line, and applying a third voltage to a control line connected to the first transistor, wherein the first voltage is positive and the third voltage is negative, wherein a difference between the second voltage and the third voltage is smaller than a difference between the first voltage and the third voltage.
